(19) United States
(12) Patent Application Publication
(10) Pub. No.: US 2024/0213336 A1
(43) Pub. Date: Jun. 27, 2024

(54) GATE-ALL-AROUND TRANSISTOR, METHOD FOR MANUFACTURING THE SAME, AND SEMICONDUCTOR DEVICE

(71) Applicant: INSTITUTE OF MICROELECTRONICS, CHINESE ACADEMY OF SCIENCES, Beijing (CN)

(72) Inventors: Yongliang Li, Beijing (CN); Fei Zhao, Beijing (CN)

(21) Appl. No.: 18/522,198

(22) Filed: Nov. 28, 2023

(30) Foreign Application Priority Data
Dec. 21, 2022 (CN) 202211652172.8

(51) Int. Cl. H01L 29/417; H01L 29/06; H01L 29/40; H01L 29/423; H01L 29/66; H01L 29/775

(52) U.S. Cl. CPC H01L 29/41733; H01L 29/0673; H01L 29/401; H01L 29/42392; H01L 29/66439; H01L 29/66545; H01L 29/775

(57) ABSTRACT

A gate-all-around transistor is provided, including: a semiconductor substrate, a nanostructure, a gate stack structure and a gate length defining structure. In a length direction of the nanostructure, each layer of nanostructure includes a source region, a drain region, and a channel region between the two. Materials of the source region and drain region include a first metal semiconductor compound. The gate stack structure surrounds the channel region. In a length direction of the gate stack structure, a sidewall of the gate stack structure is recessed relative to a sidewall of the channel region to form a recess, and the gate length defining structure is filled in the recess. The gate length defining structure is made of a second metal semiconductor compound, and a semiconductor material for making the second metal semiconductor compound is different from that for making the first metal semiconductor compound.

### CROSS-REFERENCE TO RELATED APPLICATION(S)

This application claims priority to Chinese Patent Application No. 202211652172.8, filed on Dec. 21, 2022, the disclosure of which is incorporated herein by reference in its entirety.

### TECHNICAL FIELD

The present disclosure relates to the field of semiconductor technology, and in particular, to a gate-all-around transistor, a method for manufacturing a gate-all-around transistor, and a semiconductor device.

### BACKGROUND

Compared with a planar transistor and a fin-type field effect transistor, a gate-all-around transistor has advantages such as a higher gate control capability, etc., which may improve a working performance of a semiconductor device of the gate-all-around transistor. The above-mentioned gate-all-around transistor includes inner spacers formed between a source region structure and a gate stack structure and between a drain region structure and the gate stack structure, so as to limit a length of the gate stack structure through the inner spacers.

However, the formation process of the inner spacer in the above-mentioned gate-all-around transistor is complex, which may reduce the efficiency of manufacturing the gate-all-around transistor.

### SUMMARY

The present disclosure provides a gate-all-around transistor, a method for manufacturing a gate-all-around transistor and a semiconductor device, which may be used to simplify a manufacturing process of the gate-all-around transistor while defining a length of a gate stack structure.

The present disclosure provides a gate-all-around transistor, including: a semiconductor substrate;
at least one layer of nanostructure formed on the semiconductor substrate, wherein a gap is between each layer of nanostructure and the semiconductor substrate; in a length direction of the nanostructure, each layer of nanostructure comprises a source region, a drain region, and a channel region between the source region and the drain region; and a material of the source region and a material of the drain region comprise a first metal semiconductor compound;
a gate stack structure formed on the semiconductor substrate, wherein the gate stack structure surrounds the channel region; and a sidewall of the gate stack structure is recessed relative to a sidewall of the channel region in a length direction of the gate stack structure to form a recess; and
a gate length defining structure filled in the recess, wherein a material of the gate length defining structure is a second metal semiconductor compound, and a semiconductor material for making the second metal semiconductor compound is different from a semiconductor material for making the first metal semiconductor compound.

Compared with the prior art, the at least one layer of nanostructure is formed on the semiconductor substrate in the gate-all-around transistor provided by the present disclosure. The material of the source region and the material of the drain region include the first metal semiconductor compound. Based on this, since a conductivity of a metal semiconductor compound is greater than a conductivity of a semiconductor material, in the case that the material of the source region and the material of the drain region include the first metal semiconductor compound, a contact resistance between the source region and a source electrode and a contact resistance between the drain region and a drain electrode may be reduced, and an electrical performance of the gate-all-around transistor may also be improved.

In addition, the gate-all-around transistor further includes the gate stack structure surrounding the channel region, where in the length direction of the gate stack structure, the sidewall of the gate stack structure is recessed relative to the sidewall of the channel region to form the recess, and the gate length defining structure of the gate-all-around transistor is filled in the recess to define the length of the gate stack structure between the gate length defining structures. The material of the gate length defining structure is the second metal semiconductor compound, and the semiconductor material for making the second metal semiconductor compound is different from the semiconductor material for making the first metal semiconductor compound. Based on this, in an actual application process, a fin-shaped structure including at least one stacked layer may be first formed on the semiconductor substrate. Each stacked layer includes a sacrificial layer and a channel layer on the sacrificial layer. Since the semiconductor material for making the second metal semiconductor compound is different from the semiconductor material for making the first metal semiconductor compound, and a material for making the channel layer and a material for making the sacrificial layer are different semiconductor materials, the material of the channel layer may be selected as the semiconductor material for making the first metal semiconductor compound, and the material of the sacrificial layer may be selected as the semiconductor material for making the second metal semiconductor compound. In this case, after removing a part of each sacrificial layer corresponding to the source region and a part of each sacrificial layer corresponding to the drain region, and after depositing a metal layer covering parts of each channel layer corresponding to the source region and drain region, a metallization processing is performed on the parts of each channel layer corresponding to the source region and drain region. In a process of forming the source region and the drain region, edge portions of each remaining sacrificial layer on two sides in a length direction may also react with the metal layer to form the gate length defining structures. Therefore, at least the source region and the drain region which may reduce the contact resistance and the gate length defining structure which is for defining the length of the gate stack structure may be simultaneously formed within a same step, and the manufacturing process of the source region, the drain region and the gate length defining structure is simple, so that the manufacturing process of the gate-all-around transistor may be simplified and the manufacturing efficiency of the gate-all-around transistor may be improved.

The present disclosure further provides a semiconductor device, including the gate-all-around transistor described above.

Compared with the prior art, advantages of the semiconductor device provided by the present disclosure may be referred to the analysis on the advantages of the above-mentioned gate-all-around transistor, which will not be repeated here.

The present disclosure further provides a method for manufacturing a gate-all-around transistor, including:
providing a semiconductor substrate;
forming at least one layer of nanostructure and a gate length defining structure on the semiconductor substrate, wherein a gap is between each layer of nanostructure and the semiconductor substrate; in a length direction of the nanostructure, the at least one layer of nanostructure comprises a source region, a drain region, and a channel region between the source region and the drain region; a material of the source region and a material of the drain region comprise a first metal semiconductor compound; a material of the gate length defining structure is a second metal semiconductor compound, and a semiconductor material for making the second metal semiconductor compound is different from a semiconductor material for making the first metal semiconductor compound; and
forming a gate stack structure on the semiconductor substrate, wherein the gate stack structure surrounds the channel region; a sidewall of the gate stack structure is recessed relative to a sidewall of the channel region in a length direction of the gate stack structure to form a recess; and the gate length defining structure is filled in the recess.

Compared with the prior art, advantages of the method for manufacturing the gate-all-around transistor provided by the present disclosure may be referred to the analysis on the advantages of the above-mentioned gate-all-around transistor, which will not be repeated here.

### BRIEF DESCRIPTION OF THE DRAWINGS

Accompanying drawings described herein are used to provide a further understanding of the present disclosure, which constitute a part of the present disclosure. Exemplary embodiments of the present disclosure and descriptions thereof are used to explain the present disclosure and do not constitute an inappropriate limitation to the present disclosure, in which:

FIG. 1 shows a first schematic structural diagram of a gate-all-around transistor during a manufacturing process according to embodiments of the present disclosure;

FIG. 2 shows a second schematic structural diagram of a gate-all-around transistor during a manufacturing process according to embodiments of the present disclosure;

FIG. 3 shows a third schematic structural diagram of a gate-all-around transistor during a manufacturing process according to embodiments of the present disclosure;

FIG. 4 shows a fourth schematic structural diagram of a gate-all-around transistor during a manufacturing process according to embodiments of the present disclosure;

FIG. 5 shows a fifth schematic structural diagram of a gate-all-around transistor during a manufacturing process according to embodiments of the present disclosure;

FIG. 6 shows a sixth schematic structural diagram of a gate-all-around transistor during a manufacturing process according to embodiments of the present disclosure;

FIG. 7 shows a seventh schematic structural diagram of a gate-all-around transistor during a manufacturing process according to embodiments of the present disclosure;

FIG. 8 shows an eighth schematic structural diagram of a gate-all-around transistor during a manufacturing process according to embodiments of the present disclosure;

FIG. 9 shows a ninth schematic structural diagram of a gate-all-around transistor during a manufacturing process according to embodiments of the present disclosure;

FIG. 10 shows a tenth schematic structural diagram of a gate-all-around transistor during a manufacturing process according to embodiments of the present disclosure;

FIG. 11 shows an eleventh schematic structural diagram of a gate-all-around transistor during a manufacturing process according to embodiments of the present disclosure;

FIG. 12 shows a twelfth schematic structural diagram of a gate-all-around transistor during a manufacturing process according to embodiments of the present disclosure;

FIG. 13 shows a thirteenth schematic structural diagram of a gate-all-around transistor during a manufacturing process according to embodiments of the present disclosure;

FIG. 14 shows a fourteenth schematic structural diagram of a gate-all-around transistor during a manufacturing process according to embodiments of the present disclosure;

FIG. 15 shows a fifteenth schematic structural diagram of a gate-all-around transistor during a manufacturing process according to embodiments of the present disclosure;

FIG. 16 shows a sixteenth schematic structural diagram of a gate-all-around transistor during a manufacturing process according to embodiments of the present disclosure; and

FIG. 17 shows a flowchart of a method for manufacturing a gate-all-around transistor according to embodiments of the present disclosure.

Description of reference numerals: 11—semiconductor substrate; 12—shallow groove isolation structure; 13—fin-shaped structure; 131—stacked layer; 1311—sacrificial layer; 1312—channel layer; 14—first region; 15—second region; 16—third region; 17—sacrificial gate; 18—gate spacer; 19—metal layer; 20—source region; 21—drain region; 22—first material portion; 23—second material portion; 24—gate-length control structure; 25—dielectric layer; 26—first contact hole; 27—second contact hole; 28—source electrode; 29—drain electrode; 30—channel region; 31—gate stack structure; 311—gate dielectric layer; and 312—gate.

### DETAILED DESCRIPTION OF EMBODIMENTS

Embodiments of the present disclosure will be described below with reference to the accompanying drawings. However, it will be understood that these descriptions are merely exemplary and are not intended to limit the scope of the present disclosure. In addition, in the following, descriptions for well-known structures and technologies are omitted to avoid unnecessarily obscuring the concept of the present disclosure.

Various schematic structural diagrams according to embodiments of the present disclosure are shown in the drawings. These drawings are not drawn to scale, in which some details are exaggerated and may be omitted for clear expression. Shapes of various regions and layers shown in the figure, as well as their relative sizes and positional relationships, are only exemplary, and may be deviated due to manufacturing tolerances or technical limitations in actual production, and those skilled in the art may additionally design regions/layers with different shapes, sizes and relative positions according to actual needs.

In the context of the present disclosure, when a layer/element is referred to as being located “on” another layer/element, the layer/element may be directly on the other layer/element, or there may be an intermediate layer/element therebetween. In addition, if a layer/element is located “on” another layer/element in one orientation, the layer/element may be located “under” the other layer/element when the orientation is reversed. In order to make to-be-solved technical problems, technical solutions and advantages of the present disclosure clearer, the present disclosure will be further explained in detail in combination with the accompanying drawings and embodiments. It will be understood that the specific embodiments described herein are only for explaining the present disclosure, and are not intended to limit the present disclosure.

In addition, terms “first” and “second” are only used for description, and may not be understood as indicating or implying relative importance or implicitly indicating the number of indicated technical features. Therefore, features defined with “first” and “second” may include one or more of these features explicitly or implicitly. In the descriptions of the present disclosure, “a plurality of” means two or more, unless otherwise specifically defined. The meaning of “several” means one or more than one, unless otherwise specified.

In the descriptions of the present disclosure, it will be noted that unless otherwise specified and limited, terms “installation”, “interconnection” or “connection” should be broadly understood, for example, it may be a fixed connection, a detachable connection or an integral connection; it may be a mechanical connection or an electrical connection; it may be a direct connection, may also be an indirect connection through an intermediation, or may be an internal communication between two elements or an interaction between two elements. For those skilled in the art, the specific meaning of the above-mentioned terms in the present disclosure may be understood according to specific situations.

A channel in a gate-all-around transistor has at least one layer of nanowire or at least one layer of nanosheet. A gap is provided between each layer of nanowire or nanosheet and a semiconductor substrate. In a case that the gate-all-around transistor includes at least two layers of nanowires or nanosheets, a gap is also provided between adjacent nanowires or adjacent nanosheets. Based on this, a gate stack structure in the gate-all-around transistor may surround a corresponding part of each layer of nanowire or nanosheet by providing the gate stack structure in the gap. In other words, the gate stack structure included in the gate-all-around transistor may be formed not only on a top of each layer of nanowire or nanosheet and on a sidewall of the layer of nanowire or nanosheet in a width direction, but also at a bottom of the layer of nanowire or nanosheet. Therefore, compared with a planar transistor and a fin-type field effect transistor, the gate-all-around transistor has advantages such as a higher gate control capability, etc., which may improve a working performance of a semiconductor device including the gate-all-around transistor. In an actual application process, the above-mentioned gate-all-around transistor includes an inner spacer formed between a source region and the gate stack structure and an inner spacer formed between a drain region and the gate stack structure, so that a length of the gate stack structure may be defined through the inner spacers.

However, a formation process of the inner spacer in the above-mentioned gate-all-around transistor is complex, and a manufacturing efficiency of the gate-all-around transistor may be thus reduced. A process of manufacturing a gate-all-around transistor will be simply introduced below by taking that the channel in the gate-all-around transistor has two layers of nanowires or nanosheets as an example. First, a fin-shaped structure is formed on a semiconductor substrate. In a thickness direction of the semiconductor substrate, the fin-shaped structure includes two stacked layers. Each stacked layer includes a sacrificial layer and a channel layer on the sacrificial layer. In a length direction of the fin-shaped structure, the fin-shaped structure includes a first region, a second region, and a third region between the first region and the second region. Next, a sacrificial gate and a gate spacer which cross the third region are formed. The gate spacer is formed at least on two sides of the sacrificial gate in the length direction. Then, a portion of the fin-shaped structure in the first region and a portion of the fin-shaped structure in the second region are removed, so that edge portions of the third region on two sides of the third region in the length direction are exposed. Edge portions of each remaining sacrificial layer on two sides of the remaining sacrificial layer in a length direction are removed to form recesses. Next, inner spacers filled in the recesses are formed by using processes such as deposition, etching, etc. By using a process such as epitaxial growth, a source region is formed at least in the first region and a drain region is formed at least in the second region. Then, a metallization processing may be performed on surfaces of the source region and drain region, so as to form a metal semiconductor compound on the surfaces of the source region and drain region, which may reduce a contact resistance. A dielectric layer covering the semiconductor substrate is formed, and then the sacrificial gate and the remaining sacrificial layer are removed, so that a part of each channel layer in the third region forms a respective nanowire or nanosheet. Since the inner spacers and the sacrificial layer have an etching selectivity ratio and the remaining sacrificial layer is between the inner spacers, a length of a region for forming the gate by removing the remaining sacrificial layer may be easily controlled. Finally, a gate stack structure surrounding each layer of nanowire or nanosheet is formed.

According to the manufacturing process described above, in order to form the inner spacers, an etching process is required to remove the parts of the fin-shaped structure in the first region and second region, and also, at least the deposition and etching processes are required to form the inner spacers filled in the recesses. In addition, in order to reduce a source contact resistance and a drain contact resistance, the surfaces of the source region and drain region are also required to be metallized by using processes such as deposition, annealing etching, etc., so as to form the metal semiconductor compound on the surfaces of the source region and drain region. Moreover, the above-mentioned inner spacer and metal semiconductor compound may be formed through different operation steps, so that the manufacturing process of the gate-all-around transistor may be complex and the manufacturing efficiency of the gate-all-around transistor may be reduced.

In order to solve the above-mentioned technical problems, embodiments of the present disclosure provide a gate-all-around transistor, a method for manufacturing a gate-all-around transistor, and a semiconductor device. In the gate-all-around transistor provided by the embodiments of the present disclosure, a material of a source region and drain region include a first metal semiconductor compound. A gate length defining structure for defining a length of a gate stack structure is made of a second metal semiconductor compound. A semiconductor material for making the second metal semiconductor compound is different from a semiconductor material for making the first metal semiconductor compound, so that the source region, the drain region and the gate length defining structure may be simultaneously formed in a same step, thereby simplifying the manufacturing process of the gate-all-around transistor and improving the manufacturing efficiency of the gate-all-around transistor.

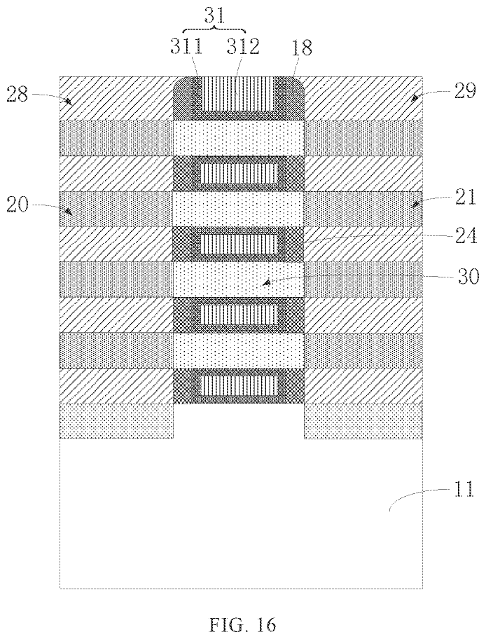

As shown in FIG. 16, the embodiments of the present disclosure provide a gate-all-around transistor. The gate-all-around transistor includes: a semiconductor substrate, a nanostructure, a gate stack structure 31 and a gate length defining structure 24.

As shown in FIG. 16, at least one layer of nanostructure is formed on the semiconductor substrate. A gap is provided between each layer of nanostructure and the semiconductor substrate. In a length direction of the nanostructure, each layer of nanostructure includes a source region 20, a drain region 21, and a channel region 30 between the source region 20 and the drain region 21. A material of the source region 20 and a material of the drain region 21 include a first metal semiconductor compound. The gate stack structure 31 is formed on the semiconductor substrate. The gate stack structure 31 surrounds the channel region 30. In a length direction of the gate stack structure 31, a sidewall of the gate stack structure 31 is recessed relative to a sidewall of the channel region 30, so as to form a recess. The gate length defining structure 24 is filled in the recess. A material of the gate length defining structure 24 is a second metal semiconductor compound, and a semiconductor material for making the second metal semiconductor compound is different from a semiconductor material for making the first metal semiconductor compound.

Specifically, the above-mentioned semiconductor substrate may be a silicon substrate, a germanium silicon substrate, a germanium substrate, a silicon-on-insulator substrate or other semiconductor substrates on which no structure is formed. Alternatively, the semiconductor substrate may also be a semiconductor substrate on which some structures are formed. Specifically, the specific structure of the semiconductor substrate may be designed as desired, and will not be specifically limited here.

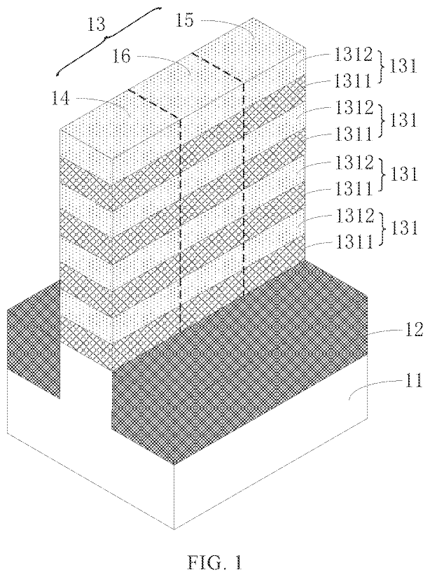

For example, as shown in FIG. 1, if the gate-all-around transistor provided by the embodiments of the present disclosure is applied to a semiconductor device as a first layer of gate-all-around transistor, the semiconductor substrate may include a semiconductor substrate 11, and a shallow groove isolation structure 12 that is used to isolate different active regions of the semiconductor substrate 11. The shallow groove isolation structure 12 may be made of an insulating material such as SiN, Si₃N₄, SiO₂, SiCO.

For another example, if the gate-all-around transistor provided by the embodiments of the present disclosure is applied to a semiconductor device as a second layer or higher layer of gate-all-around transistor, the semiconductor substrate may at least include the semiconductor substrate, a first-layer device structure formed on the semiconductor substrate, and a dielectric layer covering the first-layer device structure. In this case, a material of each portion included in the semiconductor substrate may be selected according to actual needs, as long as the material is able to be applied to the gate-all-around transistor provided by the embodiments of the present disclosure.

For the above-mentioned nanostructure, the gate-all-around transistor may include only one layer of nanostructure, or may include a plurality of layers of nanostructures. As shown in FIG. 16, when the gate-all-around transistor includes a plurality of layers of nanostructures, the plurality of layers of nanostructures are arranged at intervals in the thickness direction of the semiconductor substrate. Specifically, a height of a gap between each layer of nanostructure and the semiconductor substrate, and a height of a gap between adjacent layers of nanostructures may be determined according to a thickness of the gate stack structure 31, and will not be specifically limited here.

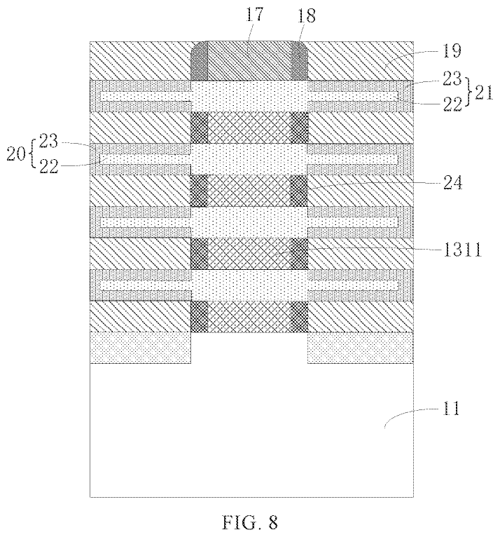

In terms of materials, a material of the channel region included in each layer of nanostructure is a semiconductor material. As shown in FIG. 16, a material of the source region 20 and the drain region 21 included in the nanostructure may include only a first metal semiconductor material. Alternatively, as shown in FIG. 8, each of the source region 20 of each layer of nanostructure and the drain region 21 of each layer of nanostructure includes a first material portion 22 and a second material portion 23 surrounding the first material portion 22. A material of the first material portion 22 is a semiconductor material. A material of the second material portion 23 is a first metal semiconductor compound, which is a compound composed of the above-mentioned semiconductor material and a metal.

In an actual application process, whether the material of the source region and the drain region include only the first metal semiconductor material, or the material of the source region and the drain region include the first metal semiconductor material and the semiconductor material for making the first material portion, the semiconductor material for making the first metal semiconductor compound is the same as the material of the channel region.

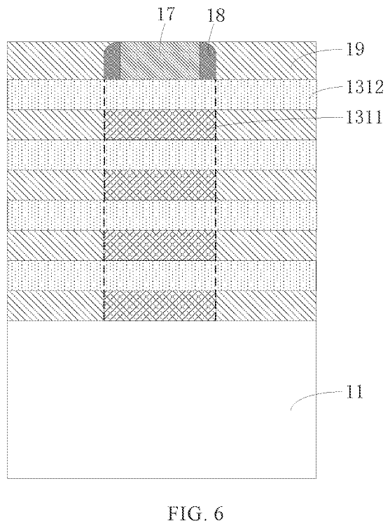

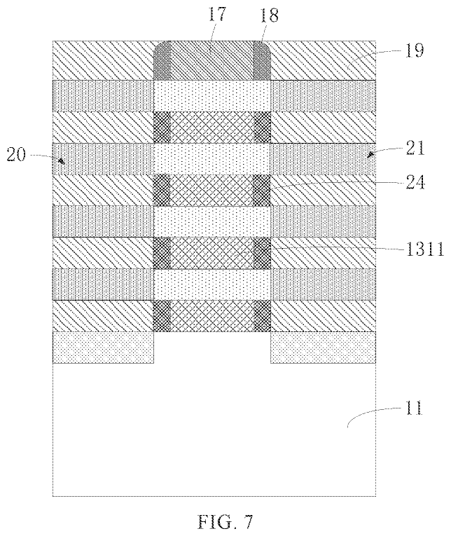

In addition, a type of the material of the source region and the drain region may be determined according to an actual manufacturing process. As shown in FIG. 6 and FIG. 7, when a part of the channel layer 1312 in a first region and a part of the channel layer 1312 in a second region are metallized, if a time of the metallization processing is long, the parts of the channel layer 1312 in the first region and the second region may completely react with a metal layer 19, so that the material of the source region 20 and the drain region 21 in this case is only the first metal semiconductor compound. As shown in FIG. 6 and FIG. 8, when the the part of the channel layer 1312 in the first region and the part of the channel layer 1312 in the second region are metallized, if the time of the metallization processing is short, only surfaces of the parts of the channel layer 1312 in the first region and the second region may react with the metal layer 19, so that the material of the source region 20 and the drain region 21 in this case include both the semiconductor material and the first metal semiconductor compound.

For example, the above-mentioned semiconductor material may be any one of semiconductor materials such as silicon, germanium silicon, germanium, or a III-V compound. The above-mentioned first metal semiconductor compound may be a compound formed by a reaction between any metal and the above-mentioned semiconductor material, as long as the compound is able to be applied to the gate-all-around transistor provided by the embodiments of the present disclosure.

For the above-mentioned gate stack structure, as shown in FIG. 16, the gate stack structure 31 may include a gate dielectric layer 311 and a gate electrode 312. The gate dielectric layer 311 is formed around the channel region 30 in each layer of nanostructure. A material of the gate dielectric layer 311 may be an insulating material such as HfO₂, ZrO₂, TiO₂, or Al₂O₃. The gate electrode 312 is provided on the gate dielectric layer 311. A material of the gate electrode 312 may be a conductive material such as TiN, TaN, or TiSiN.

For the above-mentioned gate length defining structure, the gate length defining structure is made of the second metal semiconductor compound. That the semiconductor material for making the second metal semiconductor compound is different from the semiconductor material for making the first metal semiconductor compound may refer to that: the semiconductor material for making the second metal semiconductor compound and the semiconductor material for making the first metal semiconductor compound are of different types. For example, in a case that the semiconductor material for making the first metal semiconductor compound is silicon, the semiconductor material for making the second metal semiconductor compound may be a semiconductor material such as germanium or a III-V compound

That the semiconductor material for making the second metal semiconductor compound is different from the semiconductor material for making the first metal semiconductor compound may also refer to that: a type of semiconductor material for making the second metal semiconductor compound is the same as a type of semiconductor material for making the first metal semiconductor compound, but a stoichiometric ratio of elements in the semiconductor material for making the second metal semiconductor compound is different from a stoichiometric ratio of elements in the semiconductor material for making the first metal semiconductor compound. For example, when the semiconductor material for making the first metal semiconductor compound is Si_{0.2}Ge_{0.8}, the semiconductor material for making the second metal semiconductor compound may be a germanium silicon material such as Si_{0.6}Ge_{0.4}.

In addition, a metal material for manufacturing the first metal semiconductor compound is the same as a metal material for manufacturing the second metal semiconductor compound. A type of the metal material may be set according to actual needs. The metal material may be nickel, platinum, titanium or the like.

In the length direction of the gate stack structure, a width of the gate length defining structure may be set according to actual needs, and will not be specifically limited here. For example, in the length direction of the gate stack structure, the width of the gate length defining structure may be in a range of 3 nm to 10 nm. For example, the width of the gate length defining structure may be 3 nm, 4 nm, 5 nm, 6 nm, 7 nm, 8 nm, 9 nm or 10 nm. In the case that the width of the gate length defining structure is within the above range, a long-time metallization process required in the actual manufacturing process due to a large width of the gate length defining structure may be avoided, so as to further improve the manufacturing efficiency of the gate-all-around transistor, and it is also possible to avoid that the gate length defining structure fails to stop the etchant during the removal of a sacrificial layer due to a small width of the gate length defining structure, thereby ensuring that the gate length defining structure is capable of define the length of the gate stack structure.

It will be seen from the above that, as shown in FIG. 16, in the gate-all-around transistor provided by the embodiments of the present disclosure, at least one layer of nanostructure is provided on the semiconductor substrate. The material of the source region 20 and the drain region 21 of the nanostructure includes the first metal semiconductor compound. Based on this, since a conductivity of the metal semiconductor compound is greater than a conductivity of the semiconductor material, when the material of the source region 20 and the drain region 21 of the nanostructure includes the first metal semiconductor compound, not only a contact resistance between the source region 20 and a source electrode 28 and a contact resistance between the drain region 21 and a drain electrode 29 may be reduced, but also an electrical performance of the gate-all-around transistor may be improved.

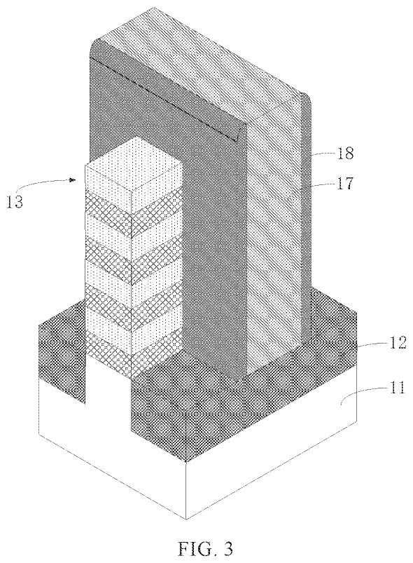

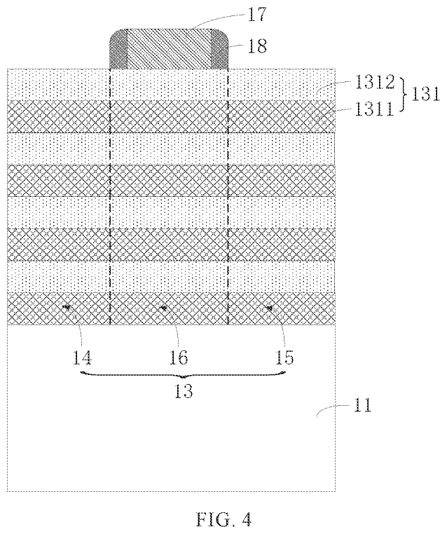

As shown in FIG. 16, the gate-all-around transistor further includes the gate stack structure 31 surrounding the channel region 30, where in the length direction of the gate stack structure 31, sidewalls of the gate stack structure 31 are recessed relative to sidewalls of the channel region 30, so as to form recesses. Gate length defining structures 24 of the gate-all-around transistor are filed in the recesses to define a length of the gate stack structure 31 between the gate length defining structures 24. The gate length defining structure 24 is made of the second metal semiconductor compound, and the semiconductor material for making the second metal semiconductor compound is different from the semiconductor material for making the first metal semiconductor compound. In this way, as shown in FIG. 1 to FIG. 9, in the actual application process, a fin-shaped structure 13 including at least one stacked layer 131 may be first formed on the semiconductor substrate. Each stacked layer 131 includes a sacrificial layer 1311 and a channel layer 1312 on the sacrificial layer 1311. Since the semiconductor material for making the second metal semiconductor compound is different from the semiconductor material for making the first metal semiconductor compound, and the material for making the channel layer 1312 and the material for making the sacrificial layer 1311 are different semiconductor materials, the semiconductor material for making the first metal semiconductor compound may be used as a material for making the channel layer 1312, and the semiconductor material for making the second metal semiconductor compound may be used as a material for making the sacrificial layer 1311. In this case, after removing parts of each sacrificial layer 1311 corresponding to the source region 20 and the drain region 21, and depositing the metal layer 19 covering the parts of the channel layer 1312 corresponding to the source region 20 and the drain region 21, the parts of the channel layer 1312 corresponding to the source region 20 and the drain region 21 are metallized. In a process of forming the source region 20 and the drain region 21, edges of each remaining sacrificial layer 1311 on two sides in a length direction of the remaining sacrificial layer 1311 may also react with the metal layer 19 to form the gate length defining structure 24. In this way, at least the source region 20 and the drain region 21 which may reduce the contact resistance and the gate length defining structure 24 which is for defining the length of the gate stack structure 31 may be simultaneously formed within the same step. Furthermore, the manufacturing process of the source region 20, the drain region 21 and the gate length defining structure 24 is simple, so that the manufacturing process of the gate-all-around transistor may be simplified and the manufacturing efficiency of the gate-all-around transistor may be improved.

In an example, as shown in FIG. 16, the above-mentioned gate-all-around transistor further includes the source electrode 28 and the drain electrode 29, and a material of the source electrode 28 and a material of the drain electrode 29 are both metal materials. The source electrode 28 is connected to the source region 20, and the drain electrode 29 is connected to the drain region 21. Specifically, the implementation of the source electrode 28 and the drain electrode 29 may include the two following cases.

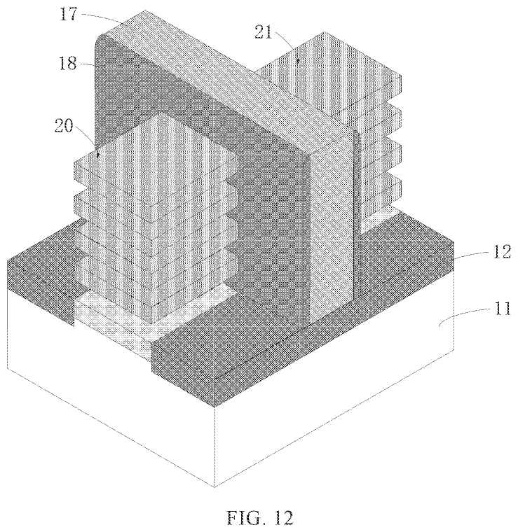

In a first case, as shown in FIG. 12 and FIG. 16, the source electrode 28 covers a periphery of the source region 20 of each layer of nanostructure and is filled between the source region 20 of each layer of nanostructure and a first structure. The first structure includes at least the semiconductor substrate. The drain electrode 29 covers a periphery of the drain region 21 of each layer of nanostructure and is filled between the drain region 21 of each layer of nanostructure and a second structure. The second structure includes at least the semiconductor substrate.

Specifically, in the first case, if the gate-all-around transistor includes only one layer of nanostructure, the first structure and the second structure respectively include only the semiconductor substrate. The source electrode covers the periphery of the source region of the nanostructure and is filled between the source region and the semiconductor substrate. The drain electrode covers the periphery of the drain region of the nanostructure and is filled between the drain region and the semiconductor substrate.

If the gate-all-around transistor includes a plurality of layers of nanostructures, the first structure and the second structure are source regions of adjacent layers and the semiconductor substrate, respectively. The source electrode covers the periphery of the source region of each layer of nanostructure and is filled between the source regions of adjacent layers of nanostructures and between the source regions and the semiconductor substrate. The drain electrode covers the periphery of the drain region of each layer of nanostructure, and is filled between drain regions of adjacent layers of nanostructures and between the drain regions and the semiconductor substrate.

In addition, in the first case, the gate-all-around transistor may further include a dielectric layer. The dielectric layer covers the semiconductor substrate, and a top of the dielectric layer is flush with a top of the gate stack structure. Both the source electrode and the drain region penetrate the dielectric layer. A material of the dielectric layer may be an insulating material such as silicon oxide, or silicon nitride.

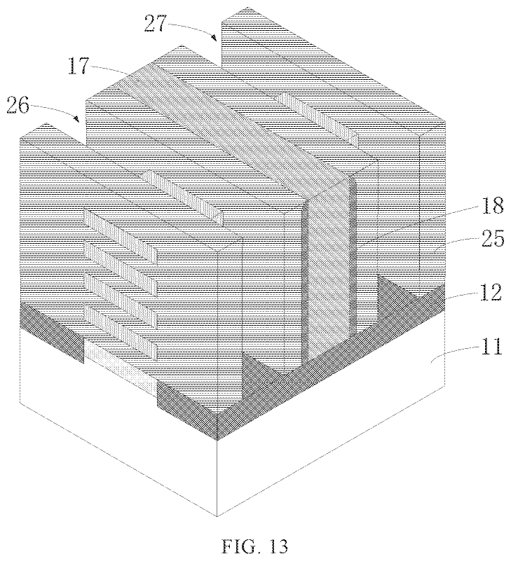

In a second case, as shown in FIG. 13, the above-mentioned gate-all-around transistor further includes: a dielectric layer 25, the source electrode and the drain electrode. The dielectric layer 25 covers the semiconductor substrate. A top of the dielectric layer 25 is flush with a top of the gate stack structure 31. A first contact hole 26 and a second contact hole 27 penetrating the dielectric layer 25 in the thickness direction of the semiconductor substrate are provided in the dielectric layer 25. The first contact hole 26 exposes a part of the source region 20 of each layer of nanostructure and the second contact hole 27 exposes a part of the drain region 21 of each layer of nanostructure. The source electrode is filled in the first contact hole 26. The drain electrode is filled in the second contact hole 27.

Specifically, in the second case, specific widths of the first contact hole and the second contact hole in the length direction of the gate stack structure may be set according to actual needs, as long as the they are less than lengths of the source region and the drain region in the length direction of the gate stack structure, respectively.

The material of the source electrode and the material of the drain electrode in the first case and the second case may be metal materials such as titanium nitride, tungsten, copper, silver, or gold.

It will be noted that the material of the source electrode and the material of the drain electrode are both metal materials, and a conductivity of the metal material is greater than a conductivity of the metal semiconductor compound and a conductivity of the semiconductor material, respectively. Based on this, regardless of the source electrode and the drain electrode in the first case or the source electrode and the drain electrode in the second case, compared with that the source region and the drain region are both made of a semiconductor material and respectively formed on tops of the source region and drain region, in the case that the source electrode and the drain electrode are respectively between the source region and the first structure and between the drain region and the second structure, a source-drain parasitic resistance may be reduced and an on-current of the channel region at the bottom may be increased, so that an electrical characteristic of the gate-all-around transistor may be improved.

In an example, as shown in FIG. 16, the above-mentioned gate-all-around transistor may further include gate spacers 18. The gate spacers 18 are formed at least on two sides of the gate stack structure 31 in a length direction, so as to isolate the gate stack structure 31 from other conductive structures, thereby improving the electrical characteristic of the gate-all-around transistor. A material of the gate spacer 18 may be an insulating material such as silicon oxide or silicon nitride.

Some embodiments of the present disclosure further provide a semiconductor device, which includes the gate-all-around transistor provided by the above-mentioned embodiments.

Compared with the prior art, advantages of the semiconductor device provided by the embodiments of the present disclosure may be referred to the analysis on the advantages of the above-mentioned gate-all-around transistor, which will not be repeated here.

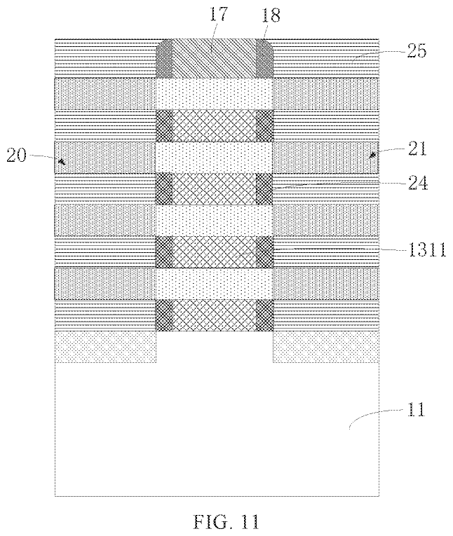

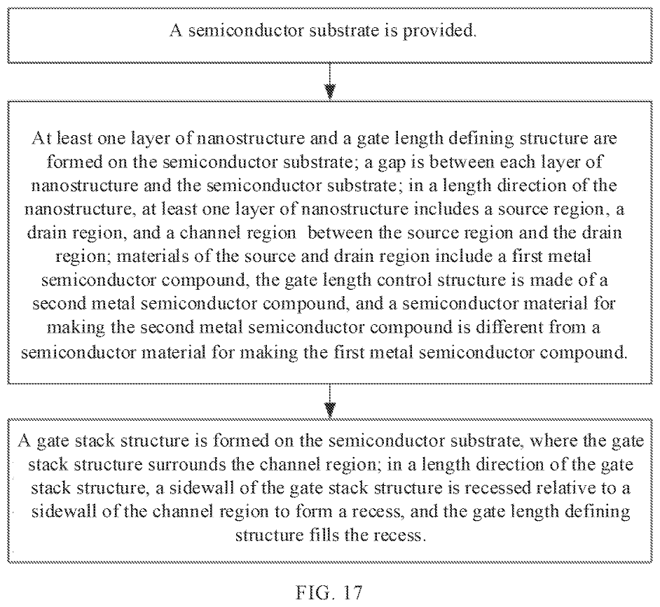

As shown in FIG. 17, some embodiments of the present disclosure further provide a method for manufacturing a gate-all-around transistor. The manufacturing process will be described below with reference to three-dimensional diagrams or sectional views in the operations shown in FIG. 1 to FIG. 16. Specifically, the method for manufacturing the gate-all-around transistor may include the following steps.

First, a semiconductor substrate is provided. Specifically, the specific structure and material of the semiconductor substrate may be referred to the above embodiments, which will not be repeated here.

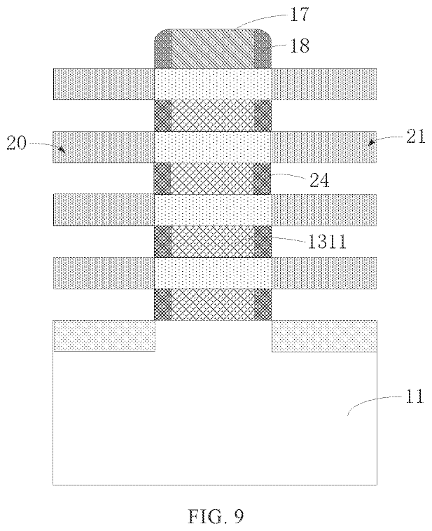

As shown in FIG. 8 and FIG. 9, at least one layer of nanostructure and a gate length defining structure 24 are formed on the semiconductor substrate. A gap is formed between each layer of nanostructure and the semiconductor substrate. In the length direction of the nanostructure, at least one layer of nanostructure includes the source region 20, the drain region 21, and a channel region between the source region 20 and the drain region 21. The material of the source region 20 and drain region 21 includes the first metal semiconductor compound. The gate length defining structure 24 is made of the second metal semiconductor compound, and the semiconductor material for making the second metal semiconductor compound is different from the semiconductor material for making the first metal semiconductor compound.

Specifically, descriptions such as the number of nanostructures formed on the semiconductor substrate, materials of the source region, the drain region and the channel region in the nanostructure may be referred to the above embodiments, which will not be repeated here.

In an actual application process, forming the at least one layer of nanostructure and the at least one gate length defining structure on the semiconductor substrate may include the following steps.

As shown in FIG. 1, a fin-shaped structure 13 is formed on the semiconductor substrate. The fin-shaped structure 13 includes at least one stacked layer 131, and each stacked layer 131 includes a sacrificial layer 1311, and a channel layer 1312 on the sacrificial layer 1311. In a length direction of the fin-shaped structure 13, the fin-shaped structure 13 has a first region 14, a second region 15, and a third region 16 between the first region 14 and the second region 15.

Specifically, the above-mentioned channel layer is used for forming the nanostructure, so that the number of the stacked layers in the fin-shaped structure is equal to the number of the nanostructures in the gate-all-around transistor. In addition, the material of the channel layer is the same as the material of the channel region in the nanostructure. Also, the material of the channel layer is the same as the semiconductor material for making the first metal semiconductor compound. The above-mentioned sacrificial layer is used for forming a gap between the nanostructure and the semiconductor substrate and a gap between adjacent layers of the nanostructures, so that a thickness of the sacrificial layer may be set with reference to the thickness of the above-mentioned gate stack structure. In addition, the sacrificial layer is also used for forming the gate length defining structure, so that the material of the sacrificial layer is the semiconductor material for making the second metal semiconductor compound.

For example, a sacrificial material layer and a channel material layer which are stacked may be formed by a process such as an epitaxial growth process. Then, the sacrificial material layer and the channel material layer which are stacked and part of the semiconductor substrate may be etched by using a process such as photolithography, etching, etc., so as to form a fin portion on the semiconductor substrate. Finally, as shown in FIG. 1, a shallow groove isolation structure 12 may be formed on a part of the semiconductor substrate exposed outside the fin portion by processes such as chemical vapor deposition, etching, etc. A top of the shallow groove isolation structure 12 is at a height less than or equal to a height at which a top of the etched part of the semiconductor substrate. A part of the fin portion exposed outside the shallow groove isolation structure 12 is the fin-shaped structure 13.

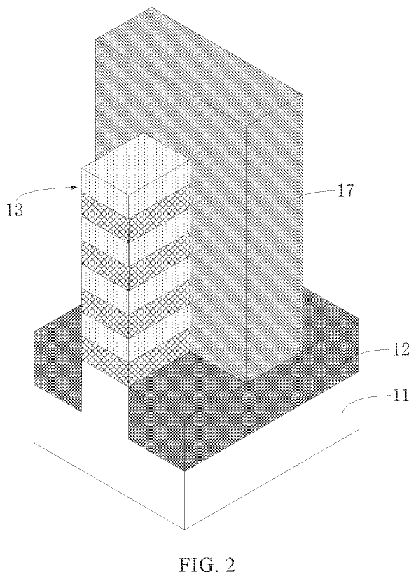

In an actual application process, the gate stack structure in the gate-all-around transistor is usually formed by using a replacement gate process, so as to improve a quality of the formed gate stack structure. In this case, after the fin-shaped structure is formed a on the semiconductor substrate and before a subsequent operation is performed, the above-mentioned method for manufacturing the gate-all-around transistor further includes: as shown in FIG. 2 to FIG. 4, forming a sacrificial gate 17 and gate spacers 18 crossing a part of the fin-shaped structure 13 corresponding to the third region 16, by using processes such as chemical vapor deposition, etching, etc. The gate spacers 18 are formed at least on two sides of the sacrificial gate 17 in the length direction. A material of the sacrificial gate 17 may be a material that is easily removed, such as polysilicon. The material of the gate spacer 18 may be referred to the above embodiments, which will not be repeated here.

It will be noted that, in addition to forming the above-mentioned sacrificial gate and gate spacers, a mask layer crossing the part of the fin-shaped structure corresponding to the third region may also be formed, so as to protect a part of the channel layer in the third region and a part of the sacrificial layer in the third region through the mask layer in subsequent operations. A material of the mask layer may be a material such as silicon nitride.

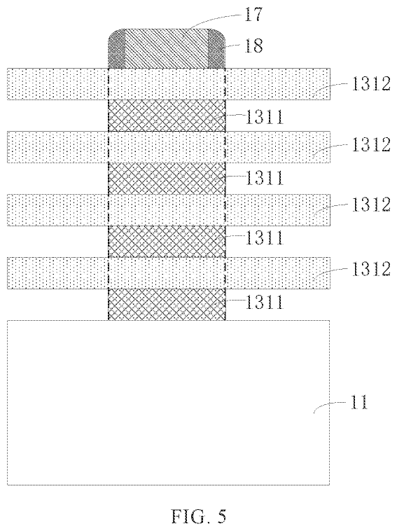

As shown in FIG. 5, parts of each sacrificial layer 1311 in the first region and the second region may be removed.

For example, the parts of each sacrificial layer in the first region and the second region may be removed by using a process such as dry etching or wet etching, using the sacrificial gate and the gate spacers (or the above-mentioned mask layer) as a mask. At this time, tops, bottoms and outer sidewalls of the parts of each channel layer located in the first region and the second region are exposed. Edge regions of each remaining sacrificial layer on two sides in a length direction are also exposed.

As shown in FIG. 7 and FIG. 8, the parts of each channel layer located in the first region and the second region and the edge regions of each remaining sacrificial layer 1311 on the two sides in the length direction are metallized, so that the part of each channel layer 1312 located in the first region forms a source region 20 of a respective layer of nanostructure, the part of each channel region 30 located in the second region forms a drain region 21 of a respective layer of nanostructure, and the edge regions of each sacrificial layer 1311 on the two sides in a length direction form gate length defining structures 24 of a respective layer of nanostructure.

For example, metallizing the parts of each channel layer located in the first region and the second region, and the edge regions of each remaining sacrificial layer on the two sides in the length direction may include the following steps.

As shown in FIG. 6, an upper metal layer 19 covering around the parts of each channel layer 1312 corresponding to the first region and the second region, and the edge regions of each remaining sacrificial layer 1311 on the two sides in the length direction is formed.

In an actual application process, the above-mentioned metal layer may be formed by using a process such as chemical vapor deposition. As shown in FIG. 6, the metal layer 19 may be filled in a gap between the source region of each layer of nanostructure and the above-mentioned first structure and a gap between the drain region of each layer of nanostructure and the above-mentioned second structure. Alternatively, a thickness of the metal layer may be relatively small, and the metal layer may cover only around the parts of each channel layer corresponding to the first region and the second region and the edge regions of each remaining sacrificial layer on the two sides in the length direction, without filled in the gap between the source region of each layer of nanostructure and the first structure and the gap between the drain region of each layer of nanostructure and the second structure. Specifically, the thickness of the metal layer may be set as desired, as long as it is able to be applied to the method for manufacturing the gate-all-around transistor provided by the embodiments of the present disclosure. In addition, a material of the metal layer may be determined with reference to the metal material for making the first metal semiconductor compound and the metal material for making the second metal semiconductor compound as described above.

For example, the metal layer may be a stacked layer composed of a titanium layer and a titanium nitride layer. The titanium nitride layer may cover the titanium layer to prevent a reaction between the titanium layer and residual oxygen in a reaction chamber during an annealing processing, so as to ensure a high quality of the formed gate length defining structure. Specifically, a thickness of the titanium layer may be in a range of 3 nm to 10 nm. A thickness of the titanium nitride layer may be in a range of 5 nm to 10 nm. The thickness of the titanium layer and the thickness of the titanium nitride layer may also be set to other appropriate values as desired, which will not be specifically limited here.

As shown in FIG. 7 and FIG. 8, an annealing processing may be performed on the formed structure, so as to form the source region 20, the drain region 21 and the gate length defining structure 24.

Specifically, conditions of the annealing processing may be determined according to a size of the channel layer, the material of the source region and drain region, and the width of the gate length defining structure in the length direction of the gate stack structure. It will be understood that in the case that the material of the source region and the drain region includes only the first metal semiconductor compound, a processing time and/or a processing temperature of the above-mentioned annealing processing may have a relatively large value. In the case that the material of the source region and the drain region includes the semiconductor material and the first metal semiconductor compound, the processing time and/or the processing temperature of the above-mentioned annealing processing may have a relatively small value.

In addition, when the width of the gate length defining structure in the length direction of the gate stack structure is small, the processing time and/or the processing temperature of the above-mentioned annealing processing may also have a relatively small value. On the contrary, when the width of the gate length defining structure in the length direction of the gate stack structure is large, the processing time and/or the processing temperature of the above-mentioned annealing processing may also have a relatively large value.

For example, the annealing processing may be performed in a nitrogen atmosphere, a temperature of the annealing processing may be in a range of 500° C. to 700° C., and the annealing time may be 30 s.

Then, as shown in FIG. 9, a remaining metal layer may be removed by using a process such as wet etching, where an etching solution used in the wet etching process may be selected as desired. For example, the remaining metal layer may be removed using an etching solution such as aqua regia.

It will be noted that, in the above-mentioned metallization processing, at least the source region and the drain region which may reduce the contact resistance and the gate length defining structure which is for defining the length of the gate stack structure may be simultaneously formed within the same step, and the manufacturing process of the source region, the drain region and the gate length defining structure is simple, so that the manufacturing process of the gate-all-around transistor may be simplified and the manufacturing efficiency of the gate-all-around transistor may be improved.

For example, as mentioned above, in the case that the manufactured gate-all-around transistor further includes the source electrode and the drain electrode, after the parts of each channel layer in the first region and the second region and the edge regions of each remaining sacrificial layer on the two sides in the length direction are metallized, and before a subsequent operation is performed, the above-mentioned method for manufacturing the gate-all-around transistor further includes: forming the source electrode and the drain electrode on the semiconductor substrate. The material of the source electrode and the material of the drain electrode are both metal materials.

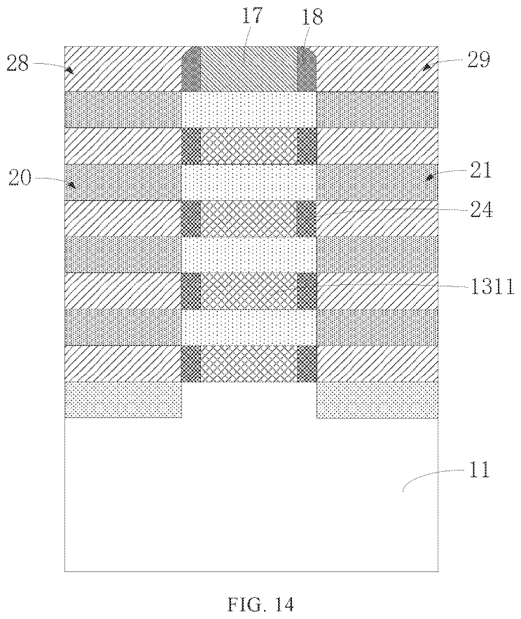

In addition, as shown in FIG. 12 and FIG. 14, the source electrode 28 may cover a periphery of the source region 20 of each layer of nanostructure and be filled between the source region 20 of each layer of nanostructure and the first structure. The first structure includes at least the semiconductor substrate. The drain electrode 29 may cover a periphery of the drain region 21 of each layer of nanostructure and be filled between the drain region 21 of each layer of nanostructure and the second structure. The second structure includes at least the semiconductor substrate. Alternatively, as shown in FIG. 13, the source electrode only is filled in the first contact hole 26 that exposes part of the source region 20, and the drain region only is filled in the second contact hole 27 that exposes part of the drain region 21.

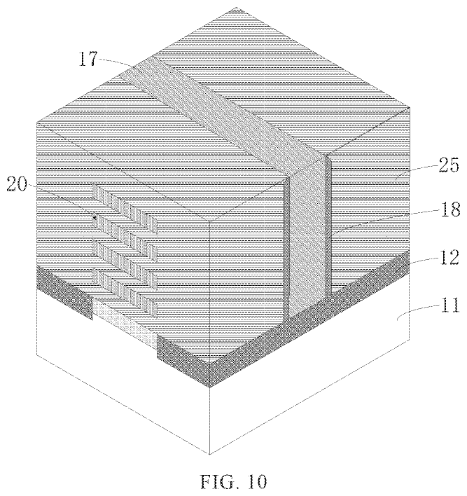

In the actual application process, regardless of the source electrode and the drain electrode having the first structure or the second structure, as shown in FIG. 10, the dielectric layer 25 covering the semiconductor substrate may be formed by using a process such as chemical vapor deposition. The top of the dielectric layer 25 is flush with the top of the gate stack structure. In this case, the sacrificial gate 17 (or the above-mentioned mask layer) is exposed outside the dielectric layer 25. The material of the dielectric layer 25 may be referred to the above embodiments. Then, a contact window penetrating the dielectric layer 25 along the thickness direction of the semiconductor substrate may be provided in the dielectric layer 25 by using processes such as photolithography, etching, etc. A width of the contact window in the length direction of the gate stack structure may be determined based on sizes of the source electrode and drain electrode.

For example, as shown in FIG. 12 and FIG. 14, when the source electrode 28 and drain electrode 29 of the first case is going to be manufactured, in the length direction of the gate stack structure, the width of the contact window corresponding to the source region 20 is greater than or equal to the length of the source region 20. In the length direction of the gate stack structure, the width of the contact window corresponding to the drain region 21 is greater than or equal to the length of the drain region 21.

For another example, as shown in FIG. 13, when the source electrode and the drain electrode of the second case is going to be manufactured, the contact window corresponding to the source region is namely the first contact hole 26, and the contact window corresponding to the drain region is namely the second contact hole 27. In this case, forming the contact window which penetrates the dielectric layer 25 in the thickness direction of the semiconductor substrate in the dielectric layer 25 includes: forming the first contact hole 26 and second contact hole 27 which penetrate the dielectric layer 25 in the thickness direction of the semiconductor substrate in the dielectric layer 25. The first contact hole 26 exposes a part of the source region of each layer of nanostructure, and the second contact hole 27 exposes a part of the drain region of each layer of nanostructure.

As shown in FIG. 14, in the first case, the source electrode 28 and the drain electrode 29 may be formed in respective contact windows by using a deposition process. In the second case, the source electrode filled in the first contact hole and the drain electrode filled in the second contact hole may be formed by using a deposition process.

Finally, as shown in FIG. 16, the gate stack structure 31 is formed on the semiconductor substrate. The gate stack structure 31 surrounds the channel region 30. In the length direction of the gate stack structure 31, the sidewalls of the gate stack structure 31 are recessed relative to the sidewalls of the channel region 30, so as to form recesses. The gate length defining structures 24 are filled in the recesses.

Specifically, the specific structure and material of each structure included in the gate stack structure may be referred to the above embodiments, which will not be repeated here.

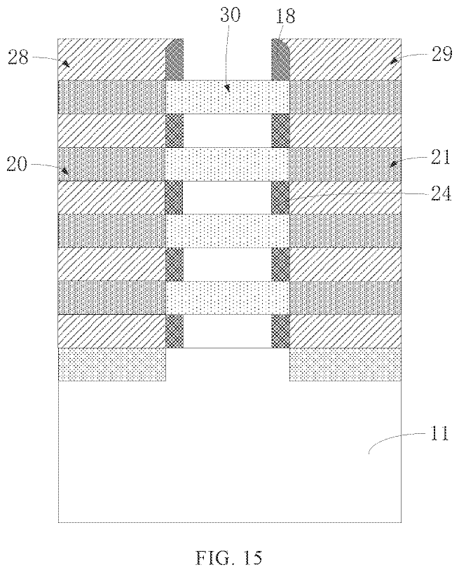

In the actual application process, before the gate stack structure is formed, the sacrificial gate (or the above-mentioned mask layer) may be first removed by using a process such as dry etching or wet etching, so as to expose the remaining sacrificial layer. Then, as shown in FIG. 15, a part of each sacrificial layer between the gate length defining structures 24 may be removed by using a process such as dry etching or wet etching, so that the part of each channel layer in the third region forms a channel region 30 of a respective layer of nanostructure. Finally, as shown in FIG. 16, a gate stack structure 31 surrounding a channel region 30 of each layer of nanostructure may be formed by using a process such as atomic layer deposition.

Compared with the prior art, the advantages of the method for manufacturing a gate-all-around transistor provided by the embodiments of the present disclosure may be referred to the analysis on the advantages of the above-mentioned gate-all-around transistor, which will not be repeated here.

In the above-mentioned description, the technical details such as patterning and etching of each layer are not described in detail. However, those skilled in the art will understand that various technical means may be used to form layers, regions, etc. of desired shapes. In addition, in order to form the same structure, those skilled in the art may further design a method that is not exactly the same as the method described above. In addition, although the various embodiments have been described above separately, this does not mean that the measures in the various embodiments may not be advantageously used in combination.

Embodiments of the present disclosure have been described above. However, the examples are for illustration only, and are not intended to limit the scope of the present disclosure. The scope of the present disclosure is defined by the appended claims and their equivalents. Without departing from the scope of the present disclosure, those skilled in the art may make various substitutions and modifications, and these substitutions and modifications should all fall within the scope of the present disclosure.

What is claimed is:

1. A gate-all-around transistor, comprising:
a semiconductor substrate;
at least one layer of nanostructure formed on the semiconductor substrate, wherein:
a gap is between each layer of nanostructure and the semiconductor substrate;
in a length direction of the nanostructure, each layer of nanostructure comprises a source region, a drain region, and a channel region between the source region and the drain region; and
a material of the source region and a material of the drain region comprise a first metal semiconductor compound;
a gate stack structure formed on the semiconductor substrate, wherein:
the gate stack structure surrounds the channel region; and
a sidewall of the gate stack structure is recessed relative to a sidewall of the channel region in a length direction of the gate stack structure to form a recess; and
a gate length defining structure filled in the recess, wherein a material of the gate length defining structure is a second metal semiconductor compound, and a semiconductor material for making the second metal semiconductor compound is different from a semiconductor material for making the first metal semiconductor compound.

2. The gate-all-around transistor according to claim 1, wherein:
the gate-all-around transistor further comprises a source electrode and a drain electrode, and a material of the source electrode and a material of the drain electrode are both metal materials;
the source electrode covers a periphery of a source region of each layer of nanostructure and is filled between the source region of each layer of nanostructure and a first structure, wherein the first structure comprises at least the semiconductor substrate; and
the drain electrode covers a periphery of a drain region of each layer of nanostructure and is filled between the drain region of each layer of nanostructure and a second structure, wherein the second structure comprises at least the semiconductor substrate.

3. The gate-all-around transistor according to claim 1, wherein the gate-all-around transistor further comprises:
a dielectric layer covering the semiconductor substrate, wherein a top of the dielectric layer is flush with a top of the gate stack structure; a first contact hole and a second contact hole penetrating the dielectric layer in a thickness direction of the semiconductor substrate are provided in the dielectric layer, the first contact hole exposing a part of the source region of each layer of nanostructure and the second contact hole exposing a part of the drain region of each layer of nanostructure;
a source electrode filled in the first contact hole; and
a drain electrode filled in the second contact hole, wherein each of a material of the drain electrode and a material of the source electrode is a metal material.

4. The gate-all-around transistor according to claim 1, wherein each of the source region of each layer of nanostructure and the drain region of each layer of nanostructure comprises a first material portion and a second material portion formed around the first material portion;
a material of the first material portion is a semiconductor material; and
a material of the second material portion is the first metal semiconductor compound, and the first metal semiconductor compound is a compound of the semiconductor material and a metal.

5. The gate-all-around transistor according to claim 1, wherein:
a type of the semiconductor material for making the second metal semiconductor compound is different from a type of the semiconductor material for making the first metal semiconductor compound; or
the type of the semiconductor material for manufacturing the second metal semiconductor compound is identical to the type of the semiconductor material for manufacturing the first metal semiconductor compound, and a stoichiometric ratio of elements in the semiconductor material for making the second metal semiconductor compound is different from a stoichiometric ratio of elements in the semiconductor material for making the first metal semiconductor compound.

6. The gate-all-around transistor according to claim 1, wherein a width of the gate length defining structure in the length direction of the gate stack structure is in a range of 3 nm to 10 nm.

7. The gate-all-around transistor according to claim 1, wherein the gate-all-around transistor comprises a plurality of layers of nanostructures that are arranged at intervals along a thickness direction of the semiconductor substrate.

8. A semiconductor device comprising the gate-all-around transistor according to claim 1.

9. A method for manufacturing a gate-all-around transistor, comprising:
providing a semiconductor substrate;
forming at least one layer of nanostructure and a gate length defining structure on the semiconductor substrate, wherein:
a gap is between each layer of nanostructure and the semiconductor substrate;
in a length direction of the nanostructure, the at least one layer of nanostructure comprises a source region, a drain region, and a channel region between the source region and the drain region;
a material of the source region and a material of the drain region comprise a first metal semiconductor compound; and
a material of the gate length defining structure is a second metal semiconductor compound, and a semiconductor material for making the second metal semiconductor compound is different from a semiconductor material for making the first metal semiconductor compound; and
forming a gate stack structure on the semiconductor substrate, wherein:
the gate stack structure surrounds the channel region;
a sidewall of the gate stack structure is recessed relative to a sidewall of the channel region in a length direction of the gate stack structure to form a recess; and
the gate length defining structure is filled in the recess.

10. The method for manufacturing the gate-all-around transistor according to claim 9, wherein the forming at least one layer of nanostructure and a gate length defining structure on the semiconductor substrate comprises:
forming a fin-shaped structure on the semiconductor substrate, wherein:
the fin-shaped structure comprises at least one stacked layer, and each stacked layer comprises a sacrificial layer and a channel layer on the sacrificial layer; and
in a length direction of the fin-shaped structure, the fin-shaped structure has a first region, a second region, and a third region between the first region and the second region;
removing a part of each sacrificial layer in the first region and a part of each sacrificial layer in the second region; and
metallizing a part of each channel layer in the first region, a part of each channel layer in the second region, and edge regions of each remaining sacrificial layer on two sides of the remaining sacrificial layer in a length direction of the remaining sacrificial layer, such that the part of each channel layer in the first region forms a source region of a respective layer of nanostructure, the part of each channel layer in the second region forms a drain region of a respective layer of nanostructure, and the edge regions of each sacrificial layer on the two sides of the sacrificial layer in the length direction of the sacrificial layer form gate length defining structures of a respective layer of nanostructure.

11. The method for manufacturing the gate-all-around transistor according to claim 10, wherein the metallizing a part of each channel layer in the first region, a part of each channel layer in the second region, and edge regions of each remaining sacrificial layer on two sides of the remaining sacrificial layer in a length direction of the remaining sacrificial layer comprises:
forming an upper metal layer covering around the part of each channel layer in the first region, the part of each channel layer in the second region, and the edge regions of each remaining sacrificial layer on the two sides of the sacrificial layer in the length direction of the sacrificial layer;
performing an annealing processing on a formed structure to form the source region, the drain region, and the gate length defining structure; and
removing a remaining metal layer.

12. The method for manufacturing the gate-all-around transistor according to claim 10, further comprising: after the fin-shaped structure is formed on the semiconductor substrate and before the part of each sacrificial layer in the first region and the part of each sacrificial layer in the second region are removed,
forming a sacrificial gate and a gate spacer that cross a part of the fin-shaped structure corresponding to the third region, wherein the gate spacer is formed at least on two sides of the sacrificial gate in the length direction of the sacrificial gate.

13. The method for manufacturing the gate-all-around transistor according to claim 10, further comprising: after the part of each channel layer in the first region, the part of each channel layer in the second region, and the edge regions of each remaining sacrificial layer on two sides of the remaining sacrificial layer in the length direction of the remaining sacrificial layer are metallized, and before the gate stack structure is formed on the semiconductor substrate,
forming a source electrode and a drain electrode on the semiconductor substrate, wherein:
each of a material of the source electrode and a material of the drain electrode is a metal material;
the source electrode covers a top of a source region of an upmost layer and is filled between a source region of each layer of nanostructure and a first structure, the first structure comprising at least the semiconductor substrate; and
the drain electrode covers a top of a drain region of an upmost layer and is filled between a drain region of each layer of nanostructure and a second structure, the second structure comprising at least the semiconductor substrate.

14. The method for manufacturing the gate-all-around transistor according to claim 10, further comprising: after the part of each channel layer in the first region, the part of each channel layer in the second region, and the edge regions of each remaining sacrificial layer on two sides of the remaining sacrificial layer in the length direction of the remaining sacrificial layer are metallized, and before the gate stack structure is formed on the semiconductor substrate,
forming a dielectric layer covering the semiconductor substrate, wherein a top of the dielectric layer is flush with a top of the gate stack structure;
providing a first contact hole and a second contact hole penetrating the dielectric layer in a thickness direction of the semiconductor substrate in the dielectric layer, the first contact hole exposing a part of a source region of each layer of nanostructure, and the second contact hole exposing a part of a drain region of each layer of nanostructure;
forming a source electrode filled in the first contact hole; and
forming a drain electrode filled in the second contact hole, wherein each of a material of the drain electrode and a material of the source electrode is a metal material.

15. The method for manufacturing a gate-all-around transistor according to claim 10, wherein the forming a gate stack structure on the semiconductor substrate comprises:
removing a part of each sacrificial layer between the gate length defining structures, such that a part of each channel layer in the third region forms a channel region of a respective layer of nanostructure; and
forming the gate stack structure surrounding a channel region of each layer of nanostructure.
